(19) United States
(12) Patent Application Publication
(10) Pub. No.: US 2015/0365084 A1
(43) Pub. Date: Dec. 17, 2015

(54) CIRCUITS AND METHODS FOR OPERATING A CIRCUIT

(71) Applicant: Infineon Technologies Austria AG, Villach (AT)

(72) Inventors: Franz Hirler, Isen (DE); Anton Mauder, Kolbermoor (DE); Jens Barrenscheen, Muenchen (DE)

(21) Appl. No.: 14/303,631

(22) Filed: Jun. 13, 2014

(51) Int. Cl. H03K 17/16

(52) U.S. Cl. CPC H03K 17/165

(57) ABSTRACT

According to various examples, circuits, detection circuits, methods for operating circuits and methods for operating power supplies are described herein. As one example, a circuit includes a transistor and a detection circuit. A voltage is coupled across two controlled terminals of the transistor and the transistor is configured to be in a non-conducting state. The detection circuit is coupled to a control terminal of the transistor. The detection circuit is configured to detect at least one of: a signal due to a voltage coupled across the two controlled terminals; a signal due to a change in the voltage coupled across the two controlled terminals; and a change in a signal at the control terminal due to a change in the voltage coupled across the two controlled terminals.

### TECHNICAL FIELD

Various embodiments relate generally to circuits, methods for operating a circuit, and methods for operating power supplies.

### BACKGROUND

Power supplies such as those connected to a mains current may have electromagnetic compatibility (EMC) filters with capacitors that are coupled across the pins of the mains outlet plug. To prevent electric shock when touching the pins, the capacitors may be discharged after removing the power supply from the mains socket. An alternating current (AC) detection circuit that is coupled to the pins may detect if the power supply is connected to mains current. However, the AC-detection circuit may require additional parts, thus increasing the costs of the power supply. Further, the AC-detection circuit may consume power. It may be necessary to deactivate the AC-detection circuit periodically to meet standby power consumption requirements.

### SUMMARY

According to one embodiment, a circuit is described herein. The circuit includes a transistor and a detection circuit. A voltage is coupled across two controlled terminals of the transistor and the transistor is configured to be in a non-conducting state. The detection circuit is coupled to a control terminal of the transistor. The detection circuit is configured to detect at least one of: a signal due to a voltage coupled across the two controlled terminals; a signal due to a change in the voltage coupled across the two controlled terminals; and a change in a signal at the control terminal due to a change in the voltage coupled across the two controlled terminals.

According to another embodiment, a method for operating a circuit is described herein. The method includes configuring a transistor to be in a conducting state to perform a function. The method further includes detecting a change in a voltage coupled between two controlled terminals of the transistor by monitoring a control terminal of the transistor.

According to still another embodiment, a method for operating a power supply is described herein. The method includes coupling a start-up circuit of a controller of a power stage of the power supply to a voltage using a transistor to provide power to the controller when the power stage is unable to provide power to the controller. The method further includes configuring the transistor to be in a non-conducting state after the power stage is able to provide power to the controller, and detecting a change in the voltage by monitoring a control terminal of the transistor when the transistor is in the non-conducting mode.

According to another embodiment, a detection circuit is described herein. The detection circuit is configured to be coupled to a control terminal of a transistor. The detection circuit is configured to detect at least one of: a signal at the control terminal due to a voltage coupled across two controlled terminals of the transistor; a signal at the control terminal due to a change in a voltage coupled across two controlled terminals of the transistor; and a change in a signal at the control terminal due to a change in a voltage coupled across two controlled terminals of the transistor.

### BRIEF DESCRIPTION OF THE DRAWINGS

In the drawings, like reference characters generally refer to the same parts throughout the different views. The drawings are not necessarily to scale, emphasis instead generally being placed upon illustrating the principles disclosed. In the drawings, the left-most digit(s) of a reference number may identify the drawing in which the reference number first appears. The same numbers may be used throughout the drawings to reference like features and components. In the following description, various embodiments are described with reference to the following drawings, in which:

FIG. 1 shows an embodiment of an equivalent circuit of a transistor;

FIG. 2 shows an embodiment of waveforms of voltage dependences of capacitances of a transistor;

FIG. 3 shows an embodiment of a circuit;

FIG. 4 shows an embodiment of waveforms in a circuit over time;

FIG. 5 shows an embodiment of a power supply; and

FIG. 6 shows an embodiment of a method for operating a power supply.

### DETAILED DESCRIPTION

The following detailed description refers to the accompanying drawings that show, by way of illustration, specific details in which the embodiments may be practiced. The word “exemplary” is used herein to mean “serving as an example, instance, or illustration”. Any embodiment or design described herein as “exemplary” is not necessarily to be construed as preferred or advantageous over other embodiments or designs.

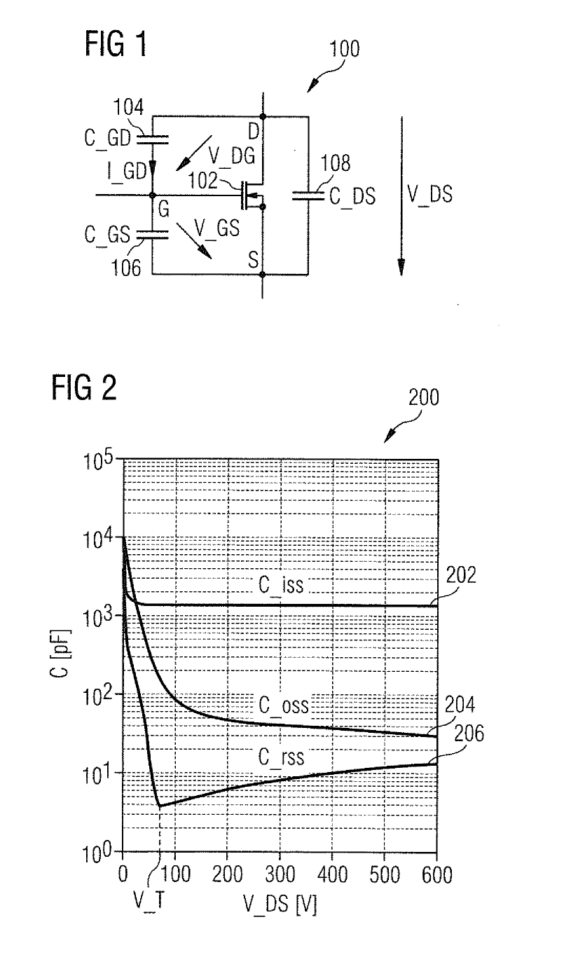

FIG. 1 shows an embodiment 100 of an equivalent circuit diagram of a switch 102. The switch may for example be a high voltage switch. A high voltage may be a voltage between 200 V to 600 V. The switch 102 may for example be a metal oxide semiconductor (MOS) field effect transistor (FET). For the purpose of illustration, a MOSFET is used as a switch 102, however, other transistors such as insulated-gate bipolar transistors (IGBT) and high-electron-mobility transistors (HEMT) may also be used. The transistor 102 may have three terminals, a gate G, a drain D and a source S. The gate G may be called a control terminal, the drain D and the source S may be called controlled terminals.

The equivalent circuit diagram of the transistor 102 may have a gate-drain capacitor 104 between the gate G and the drain D, a gate-source capacitor 106 between the gate G and the source S, and a drain-source capacitor 108 between the drain D and the source S. The gate-drain capacitor 104 may have a capacitance C_GD. The capacitance C_GD may be dependent on the drain-to-gate voltage V_DG. The gate-source capacitor 106 may have a capacitance C_GS. The capacitance C_GS may be considered to be constant, that is, not depending on the biasing or state of the transistor. The drain-source capacitor 108 may have a capacitance C_DS which may depend on the V_DS and on the switching state of the transistor, that is, if the transistor is conducting or non-conducting.

A voltage V_DS may be applied across the drain D and the source S, that is, across the two controlled terminals. The gate-drain capacitor 104 and the gate-source capacitor 106 may form a capacitive voltage divider for voltage V_DS such that:

V_{—}DS=V_{—}DG+V_{—}GS, (1)

where V_DG and V_GS are the voltages across the capacitors 104 and 106, respectively. The capacitive voltage divider may be used to detect a change in V_DS, for example by detecting a change in V_GS or a change in currents through the capacitors 104 and 106.

The capacitances C_GD, C_GS and C_DS may be difficult to measure. Instead, data sheets of transistors may provide an input capacitance C_iss, which is measured when source S and drain D are shortened for AC-currents:

C_{—}iss=C_{—}GS+C_{—}GD, (2)

an output capacitance C_oss, which is measured when source S and gate G are shortened:

C_{—}oss=C_{—}DS+C_{—}GD, and (3)

a reverse transfer capacitance C_rss:

C_{—}rss=C_GD. (4)

FIG. 2 shows an embodiment 200 of waveforms 202, 204 and 206. Waveform 202 may show how the input capacitance C_iss varies over voltage V_DS, waveform 204 may show how the output capacitance C_oss varies over voltage V_DS, and waveform 206 may show how the reverse transfer capacitance C_rss varies over voltage V_DS. C_iss, C_oss and C_rss may vary as a function of V_DS because C_GD and C_DS may vary as a function of V_DS. The waveforms 202, 204 and 206 may be measured, for example, with V_GS=0 and at a frequency of 1 MHz.

A current I_GD may flow through the gate-drain-capacitor 104 depending on the time derivate of the product of the capacitance C_GD and the voltage V_DG across the gate-drain-capacitor 104:

I_{—}GD=d(C_{—}GD·V_{—}DG)/dt. (5)

The voltage V_DG across the gate-drain-capacitor 104 may be a function of V_DS due the capacitive voltage divider formed by the gate-drain capacitor 104 and the gate-source capacitor 106. As shown in waveform 206 of FIG. 2, the capacitance C_GD (corresponding to C_rss, see Eq. (4)) itself may also depend on the voltage V_DS, so that the dividing ratio of the capacitive voltage divider may also depend on voltage V_DS as the capacitance C_GD is dependent on V_DS:

I_{—}GD=d(C_{—}GD(V_{—}DS(t))·V_{—}DG(V_{—}DS(t)))/dt. (6)

The relationship between I_GD and voltage V_DS may be non-linear. It may be difficult to determine the exact value of V_DS from I_GD. However, when V_DS changes with time, that is, when d(V_DS)/dt is non-zero, I_GD will be non-zero and will also change with time. This may be sufficient if the exact value of V_DS is unimportant, for example, if it is only desired to know if V_DS changes over time or not. Current I_GD or a change in current I_GD may be measured and a change in voltage V_DS may be detected. Any kind of change in voltage V_DS may be detected this way with very low power consumption as the transistor 102 is non-conducting, that is, it is open or OFF. For example, an AC-detection circuit may use the non-conducting transistor 102 to determine if an AC-signal is present, for example to determine if a circuit, such as a power supply, is plugged into a mains outlet. Because of the low power consumption, it is not necessary to deactivate the AC-detection circuit to meet standby power consumption requirements.

In an embodiment, the transistor 102 may be conducting. A voltage, for example V_GS, may be applied between a control terminal and one of the controlled terminals to set the transistor 102 in a conducting state. When the transistor 102 is conducting, it may have a very low resistance and a very low voltage drop may occur across its controlled terminals. Most of the supply voltage will drop across the load. However, in case of a short circuit, only a very small voltage will drop across the load. Most of the supply voltage will drop across the controlled terminals of the transistor. The voltage across the controlled terminals of the transistor , for example V_DS, will change, for example from about 0 V to about the value of the supply voltage. The change in voltage may detected as a change in voltage and/or current at the control terminal. Thus, a short circuit may be detected by monitoring a signal, such as a current flow or a voltage, at the control terminal. The monitored signal or a change in the signal may be compared to a threshold to detect the short circuit. The transistor 102 may be turned off, that is rendered to be in a non-conducting state, after a short circuit has been detected.

Due to the voltage division, the change in V_GS will be smaller than the change in V_DS and may be difficult to detect with accuracy. However, it may be desired to detect changes around small voltages V_DS, for example for zero-crossing detection. A small voltage may, for example, be less than 1 V, 5 V, 10 V, 20 V or 30 V.

The change in capacitance C_GD with changes in voltage V_DS may be large for small voltages V_DS. In other words, the capacitance C_GD may have a high sensitivity towards changes in V_DS at small voltages V_DS. As an example, waveform 206 of FIG. 2 representing the capacitance C_GD (see Eq. (4)) may decrease by two to three orders of magnitude from 10⁵ pF to 10² pF when V_DS changes from 0 V to 20 V. A high sensitivity may for example be 5,000 pF/20 V=250 pF/V. It may lie in the range of 100 . . . 500 pF/V, or 50 . . . 1,000 pF/V or 10 . . . 2,000 pF/V. Therefore C_GD may be high a small voltages, which means that also low dV_DS/dt may result in high I_GD.

A change in small values of the voltage V_DS may be reflected in the voltage V_GS due to the capacitive voltage divider and may be further amplified by the large sensitivity of the capacitance C_GD at small values of the voltage V_DS. Changes of V_DS at low voltages, for example at or near zero voltage, for example during zero crossing of an AC-signal, may then be detected with high accuracy. The detection may also be applied to detect valleys, that is, for determining minima of a signal, as the valleys may be smaller than the rest of the signal.

For detecting changes in small voltages V_DS, the transistor 102 may have a high sensitivity of V_DG and I_GD towards V_DS. However, it may be desired to reduce losses, for example due to charging and discharging of the capacitors 104 and 106, at larger values of voltage V_DS. It may be desired for C_GD to have a lower sensitivity towards changes in V_DS for larger voltages. A large voltage may for example be larger than 70 V, 80 V, 100 V, 200 V or 500 V. As an example, waveform 206 of FIG. 2 representing the capacitance C_GD (see Eq. (4)) may increase from 4 pF to 13 pF, that is by less than a magnitude, in the range of V_DS=80 V to 600 V. A low sensitivity may for example be 10 pF/500 V=0.02 pF/V. It may lie in the range of 0.01 . . . 0.05 pF/V, or 0.005 . . . 0.1 pF/V or 0.001 . . . 0.2 pF/V. Due to the low sensitivity, currents flowing in the capacitors 104 and 106 may be reduced at larger values of V_DS.

The capacitance C_GD over voltage V_DS relationship may have a corner voltage V_T. The corner voltage V_T may divide the capacitance C_GD over voltage V_DS relationship into regions with low sensitivity and high sensitivity. Capacitances C_GD for voltage V_DS below the corner voltage V_T may have a high sensitivity (or slope) over voltage V_DS. Capacitances C_GD for voltage V_DS above the corner voltage V_T may have a low sensitivity (or slope) over voltage V_DS. As an example, the waveform 206 of FIG. 2 representing the capacitance C_GD (see Eq. (4)) may have a corner voltage V_T=75 V. The corner voltage V_T may be different for different transistors 102. It may, for example, be in the range of 5 V . . . 100 V or 30 V . . . 75 V. The slope may be negative for voltages V_DS smaller than the corner voltage V_T. The slope may be positive for voltages V_DS greater than the corner voltage V_T.

The capacitance of the gate-drain capacitor of the transistor may be much larger, for example by at least a factor 20, at a low voltage coupled across the two controlled terminals than at a rated breakdown voltage of the transistor. As an example, waveform 206 of FIG. 2 representing the capacitance C_GD (see Eq. (4)) may have a value of about 10⁴ pF at a voltage of about 0 V and about 10 pF at a rated breakdown voltage V_DS=600 V.

The transistor 102 may have a non-linear C_GD(V_DS) characteristic, for example as described above. An an example, a superjunction (SJ) transistor, which may be based on a conventional MOSFET structure, may have such a non-linear C_GD(V_DS) characteristic. In an n-channel superjunction device, alternating n-doped and p-doped regions, for example in the form of pillars, replace the n-doped drift zone of a MOSFET. In an ON-state, current flows through the n-doped drift of the superjunction device regions with higher doping concentration with respect to a conventional MOSFET which lowers the on-resistance Ron. In an OFF (or blocking)-state, the charges in the p-doped regions and the n-doped regions are depleted or cancel each other to provide a high breakdown voltage Vbr. The waveforms 202, 204 and 204 of FIG. 2 may be waveforms of a superjunction transistor.

As another example, a field plate trench (FPT) transistor may also have such a desired non-linear characteristic. A field plate trench transistor may be similar to a superjunction device. However, the p-doped pillars may be replaced by source electrode which are isolated from the n-doped drift zone by a thick oxide layer.

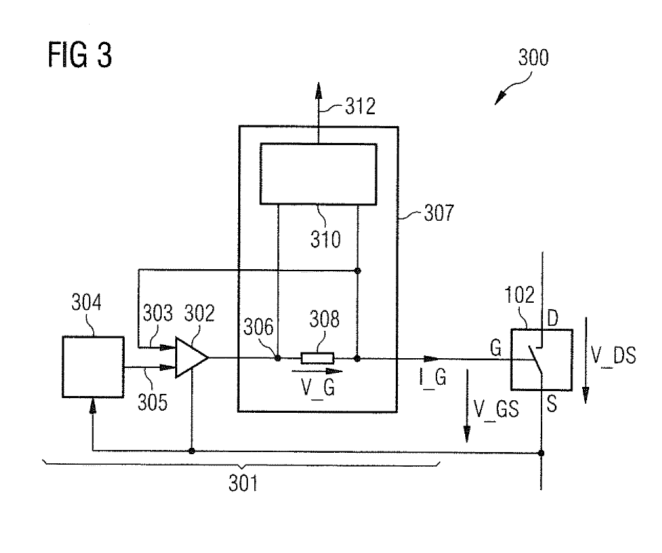

FIG. 3 shows an embodiment 300 of a circuit. The circuit may be configured to detect a change in a voltage. It may include a detecting circuit 301 coupled to a switch 102. The switch 102 may be similar or the same as the switch 102 described in conjunction with FIGS. 1 and 2. For the purpose of illustration, the switch 102 may be a transistor, for example a MOSFET or a superjunction transistor. The transistor 102 may have two controlled terminals, for example drain D and source S, and a control terminal, for example a gate G. The detecting circuit 301 may be coupled to the control terminal (or gate G) and may be configured to monitor the control terminal. It may further be coupled to one of the controlled terminals, for example, the source S. The detecting circuit 301 may monitor or measure a voltage V_GS between the gate G and the source S. It may monitor or measure a current I_G flowing through the gate G, for example, when the voltage V_GS is fixed or regulated to a constant value.

The voltage V_GS may be measured by itself, that is, without being regulated to a constant value and/or without monitoring or measuring the current I_G. However, it may be easier to detect a change in voltage V_DS by measuring the current I_G since the current I_GD through the gate-drain capacitor 104 is a time derivative, see Eq. (5), and since the transistor gate can be kept easily in an off state. A time derivative may highlight changes in signals and may eliminate parts in the signal that do not change over time.

A voltage V_DS may be applied to the transistor 102, for example between the source S and the drain D. The voltage V_DS may be any voltage. If the transistor does not have a body diode which may conduct current at one of the polarities, it may be an alternating voltage, that is a voltage that changes its polarity over time. The voltage V_DS may be a rectified voltage, that is a voltage that only has one plurality, for example a half-wave or full-wave rectified voltage.

The detecting circuit 301 may include a driver circuit 302. The driver circuit 302 may be coupled to the control terminal, for example the gate G, of the transistor 102. The driver circuit 302 may be configured to provide and regulate a signal at the control terminal of the switch (or transistor) 102. It may have a first input 303 and a second input 305. The first input 303 may be coupled to a feedback signal, for example, the signal at the gate G. The second input 305 may be coupled to a reference signal. The reference signal may set the value at an output 306 of the driver circuit 302. The driver circuit 302 may, for example, be a differential amplifier, and its output 306 may be coupled to the gate G.

As described in conjunction with FIGS. 1 and 2, a change in voltage V_DS applied to the transistor 102 may lead to a change in voltage V_GS and in current I_GD. The driver circuit 302 may be configured to regulate the signal at the control terminal to a constant voltage. It may output a current I_G to compensate changes in V_GS and I_GD. Current I_G may therefore depend on V_GS and I_GD. It may be used to indicate if a voltage V_DS is applied to the switch 102 and if the voltage V_DS changes over time. If the voltage is a half-rectified mains voltage, current I_G may be periodic with the line frequency, for example 50 Hz or 60 Hz. If the voltage is a fully-rectified mains voltage, current I_G may be periodic with twice the line frequency, for example 100 Hz or 120 Hz.

In another embodiment, the driver circuit 302 may be configured to connect the gate G to ground S by switching in an internal transistor. The current may I_G may therefore depend on V_SD=V_GD and I_GD.

The detecting circuit 301 may further include an evaluation circuit 307 configured to detect if the signal at the control terminal, for example the gate G, changes over time. The evaluation circuit 307 may include a resistor 308 and a voltage comparator 310. The resistor 308 may be coupled between the output 306 of the driver circuit 302 and the control terminal G. The voltage comparator 310 may be coupled across the resistor 308. A current I_G flowing through the resistor 308 may cause a voltage drop V_G=R·I_G across the resistor 308, where R is the resistance of the resistor 308. The voltage comparator 310 may compare the voltage drop V_G to at least one reference voltage, which may be internal to the voltage comparator 310. The at least one reference voltage may provide at least one threshold. The thresholds may have the same polarity or opposite polarities to each other. The voltage comparator 310 may provide a signal at its output 312 indicating if the voltage drop V_G is greater or less than one or more of the thresholds. The signal at its output 312 may therefore indicate if there has been an change in voltage V_DS as such a change in voltage V_DS may lead to a current I_G which may cause a voltage drop V_G to cross at least one threshold.

The transistor 102 may be configured to be in a non-conducting state, that is, in a state in which no current flows between its drain D and its source S. In a non-conducting state, the transistor 102 may be used to detect changes of voltages across its controlled terminals by monitoring a signal at its control terminal, for example at its gate G.

For example, the transistor 102 may be a normally-off transistor that does not conduct when no signal is applied to its control input. The transistor may be an enhancement-mode transistor, for example a MOSFET, which is OFF at a zero gate-source voltage V_GS=0. The enhancement-mode transistor may be turned ON by voltage V_GS being more positive than a positive threshold voltage for an N-channel device and by a voltage V_GS being more negative than a negative threshold voltage for a P-channel device. The detecting circuit 301 may set or regulate voltage V_GS to have a magnitude smaller than the magnitude of the threshold voltages to render the transistor 102 non-conducting. For example, V_GS may be set or regulated to V_GS<3 V for an N-channel device and V_GS>−3 V for a P-channel device. For example, V_GS may be set or regulated to V_GS=0 V.

For example, the transistor 102 may be a normally-on transistor that is conducting when no signal is applied to its control input. The transistor may be depletion-mode transistor, for example a MOSFET, which is ON at a zero gate-source voltage V_GS=0. The depletion-mode transistor may be turned OFF by voltage V_GS being more negative than a negative threshold voltage for an N-channel device and by a voltage V_GS being more positive than a positive threshold voltage for a P-channel device. The detecting circuit 301 may set or regulate voltage V_GS to have a magnitude greater than the magnitude of the threshold voltages to render the transistor 102 non-conducting. For example, V_GS may be set or regulated to V_GS<=−3 V for an N-channel device and V_GS>=+3 V for a P-channel device.

The detection circuit 301 may further include a driver controller 304. The driver controller 304 may be coupled to the driver circuit 302. An output of the driver controller 304 may be coupled to the second input 305 of the driver circuit 302. A reference signal provided at the output of the driver controller 304 may set the value of the signal at the control terminal that the driver circuit 302 regulates. The signal at the output of the driver controller 304 may be configured to render (or place) the transistor 102 in a conducting state or in a non-conducting state.

The detecting circuit 301 may also operate without feedback, for example by measuring voltage V_GS or detecting changes in voltage V_GS. The driver circuit 302 may be designed to have a small internal resistance, for example if the transistor 102 requires a large driving current, for example if the transistor 102 is a power transistor. However, this may lead to a small variations in the voltage V_GS at the transistor 102, which may be difficult to detect. To increase the magnitude of the voltage variations without causing high losses, for example, to be in the region of a few volts, a small transistor 102, that is with a small active area of the channel may be used A small active area may for example be 10 μm² to 1000 μm². In contrast to that, a large active area may for example be 1 mm² to 100 mm² Alternatively, transistor 102 may be a transistor of a plurality of transistors. The plurality of transistors may, for example, be a plurality of transistor cells of a power transistor. The drains of the transistors cells may be connected together and the sources of the transistors cells may be connected together. The gates of the transistors cells may be coupled together, except for the gate of transistor 102. The gate G of transistor 102 may be separate, that is, it may assume its own potential different from the potential at the gates of the other transistors cells. By monitoring a signal at its gate G, a change in voltage V_DS coupled across its source S and drain D may be detected. However, the source S and drain D of the transistor 102 may remain connected to the sources and drains of the other transistor cells.

In some embodiments, the transistor 102 may be configured to have a high threshold voltage which is higher than the magnitude of the voltage variations at its gate. In this way, the transistor 102 will not be rendered conducting by changes in voltage V_DS.

In another embodiment, the source region of the transistor 102 may be omitted or blocked by a mask, so that the transistor 102 is unable to conduct. The source electrode may be connected to the body of the transistor 102. The capacitances C_GD and C_GS are only moderately modified by omitting the Source region or increasing the threshold voltage.

The gate G of the transistor 102, for example the small transistor 102 or one of the transistor cells 102, may, for example, be connected to its source via a resistor. The resistance of the resistor may be chosen so that V_GS is in a region that is easily measured but does not place the transistor 102 into a conducting state. Alternatively, a capacitor may be placed in parallel to the capacitance C_GS of the transistor 102 to reduce the voltages V_GS below the conduction threshold. In both cases, V_GS may be limited by diodes, for example in both directions, to prevent conduction between source S and drain D.

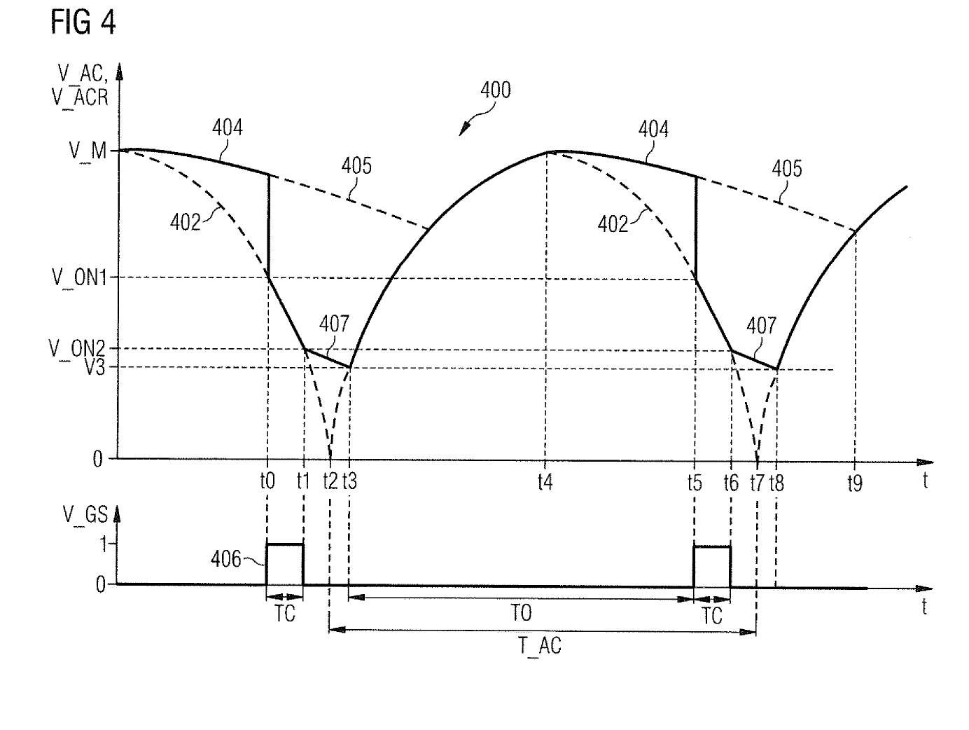

The driver controller 304 may be further configured to place the transistor 102 in a conducting state for a predetermined duration after a predetermined time after a change in voltage V_DS has been detected. FIG. 4 explains how long the predetermined time and how long the predetermined duration of the conducting state may be.

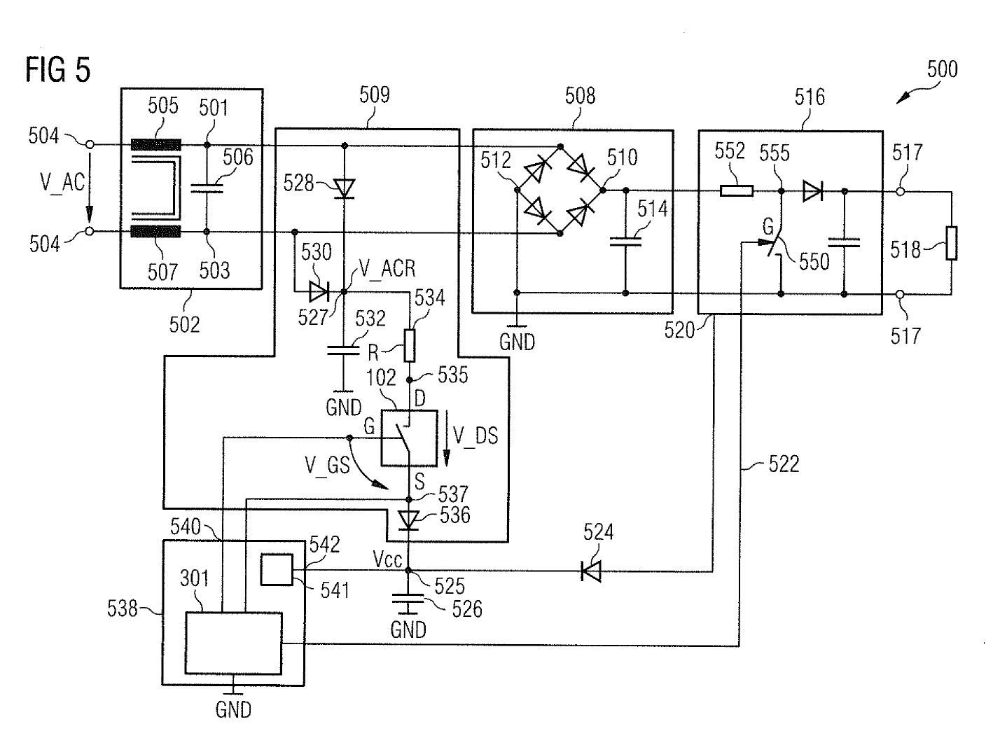

FIG. 4 shows an embodiment 400 of waveforms 402, 404 and 406 in a circuit over time t. The circuit may, for example, be the circuit described in conjunction with FIG. 5.

Waveform 402 may be an AC-voltage V_AC, for example a line or mains voltage, having an amplitude V_M of 110 V or 230 V. For the purpose of illustration and for comparison with waveform 404, it is drawn as ideally and fully rectified. Waveform 402 may have a period of T_AC, measured, for example, between times t2 and t7. If the mains voltage has a frequency of 50 Hz, the period may be T_AC=10 ms. It may be desired to detect the presence of voltage V_AC or of a change in the voltage V_AC.

Waveform 404 may be a voltage V_ACR of a voltage V_AC that is fully rectified by a real rectifier. For the purpose of illustration, it is assumed that there are no voltage drops in the rectifier and that the rectifier has a zero threshold rectification voltage. The rectified voltage V_ACR may be used to power a circuit, for example a start-up circuit or any other circuit.

Waveforms 402 and 404 may have the same waveform as 402 for some periods of time, for example during time t3 to t4. However, due to capacitances present in a real rectifier, for example due to parasitic capacitances, waveform 404 may deviate from waveform 402 for some periods of time. As an example, FIG. 5 shows diodes 528, 530 used for rectification which may have an equivalent parasitic capacitance 532. Voltage V_ACR may fail to follow voltage V_AC when voltage V_AC is falling (or has a negative slope) as it may remain at the higher voltage of the parasitic capacitors. For example, for times between time t4 and t9, waveform 404 may have a region 405 at which it may remain at a high level while waveform 402 returns to zero at time t7. During this time interval, waveform 404 cannot be used to detect if V_AC is reduced to zero, for example, if the circuit has been disconnected from the AC-supply. Even though a power supply may have been pulled out of the mains socket, its capacitor, for example an EMI-capacitor, and pins connected to it, will not be discharged since the disconnection from the AC-supply has not been detected.

Waveform 406 may present a signal at a control terminal of the transistor 102, for example the voltage V_GS between gate G and source S of the transistor 102. The voltage V_GS may be regulated by the driver circuit 302 to a constant value, for example to zero volts or another value, as explained above, so that the transistor 102 is in a non-conducting state. During the non-conducting state, transistor 102 may be used as a sensor for the voltage V_ACR by monitoring the control terminal as was described in conjunction with FIG. 3. Waveform 406 may show when transistor 102 is conducting (or closed) and non-conducting (or open). The non-conducting state is indicated by the value “0”, the conducting state is indicated by the value “1”

The driver circuit 302 may receive an input from the driver controller 304 that places the transistor 102 in a conducting state. For example, at times t0 and t5, the transistor 102 may be set to conduct as is shown by waveform 406. The parasitic capacitances may be discharged by the conducting transistor 102. At times t0 and t5, voltage V_ACR may drop to the same value V_ON1 as voltage V_AC. Voltage V_ACR may follow voltage V_AC in the time intervals t0 to t1 and t5 to t6, and may accurately represent voltage V_AC. However, when transistor 102 conducts, it may not be used as a sensor.

After a predetermined duration TC during which the transistor 102 conducts, the driver circuit 302 may receive an input from the driver controller 304 that places the transistor 102 in a non-conducting state, for example at times t1 and t6. As the transistor 102 is non-conducting, the parasitic capacitances are no longer actively discharged. The voltage V_ACR may again remain at the higher voltage of the parasitic capacitances, for example as shown by regions 407 during the time interval from t1 to t3 and time interval from t6 to t8, instead of following the voltage V_AC to zero at times t2 and t7. In another embodiment, the duration TC is not predetermined but may, for example, end when V_ACR crosses a threshold, for example if it falls below V_ON2.

Voltage V_AC may start to increase again at turnover points, for example at times t2 and t7. At times t3 and t8, voltage V_AC and voltage V_ACR may have the same value V3 and voltage V_ACR may follow voltage V_AC again.

Voltage V_ACR may be coupled to the transistor 102, for example, as described in conjunction with FIG. 5. It may therefore influence the voltage V_DS across the controlled terminals of transistor 102. The current I_G provided by the driver circuit 302 when the transistor 102 is non-conducting may therefore depend on the time derivative of the voltage V_ACR. The steeper the slope of voltage V_ACR, the higher the magnitude of the current I_G. For a sinusoidal waveform, the slope may be greatest at the zero-crossings of the waveform. Therefore, current I_G may have a maximum at zero-crossings of V_AC.

The time derivate may be modulated in amplitude due to the dependence of the capacitance C_GD on the voltage V_DS, see Eq. (6). At small voltages V_DS, the capacitance of the gate-drain capacitor 104 may have a large voltage dependence or a high sensitivity. Changes in V_AC at small voltages may therefore lead to large changes in current I_G, which may be helpful in zero-crossing detection.

For decreasing voltages V_ACR, for example, for times before time t3, current I_G may be positive. The presence of a positive current value I_G may indicate that voltage V_DS is decreasing. The positive current value I_G may be compared to at least one first threshold, for example, a positive threshold. If current I_G exceeds the first threshold, this may indicate that voltage V_DS changes and that voltages V_ACR and V_AC should be present.

For increasing voltages V_ACR, for example for times between t3 and t4, current I_G may be negative. The presence of a negative current value I_G may indicate that voltage V_DS is increasing. The negative current value I_G may be compared to at least one second threshold, for example, a negative threshold. If current I_G exceeds the second threshold, this may indicate that voltage V_DS changes and that voltages V_ACR and V_AC should be present.

When voltage V_ACR changes from decreasing to increasing, that is, when its slope changes from negative to positive, for example at times t3 and t8, the current I_G may change polarity, for example from a positive value to a negative value, or vice versa. If the change in slope of the voltage V_ACR is discontinuous, current I_G may jump in value. A polarity change in current I_G may be used to detect a zero-crossing of V_AC. The polarity change in current I_G may be detected by crossing or exceeding both the first threshold and the second threshold, where the first and the second threshold have opposite polarities. The first threshold and the second threshold may be crossed or exceeded at different times, for example, one after the other.

If the slope of V_ACR is zero, there may be no current in I_G or no change in current I_G. For example, at time t4, even though a voltage V_ACR is present, it is possible that it will not be detected, as it will not lead to a current I_G or a change in current I_G. For example, if no voltage V_ACR is present, there will also be no current I_G or a change in current I_G.

Times t0 and t5 may be set after a predetermined time interval T0 has passed. The predetermined time interval T0 may start after a change in the input signal V_DS has been detected, for example, by current I_G exceeding or crossing one or more thresholds. For example, it may start at times t3 and t8. As another example, the predetermined time interval T0 may start at times t1 and t6, for example directly after the transistor 102 stops conducting. The predetermined time interval T0 may depend on the frequency of the voltage, for example of voltage V_ACR. The frequency of the voltage may already be known, for example in case of a mains voltage, or may be measured. The predetermined time interval T0 may be set by a timer. It may be less than a period T_AC of the voltage V_ACR so that the parasitic capacitors are discharged before the next measurement. For example, it may be T0=18 ms for a voltage with a frequency of 50 Hz. It may be T0=9 ms for a fully rectified voltage with a frequency of 50 Hz, for example for voltage V_ACR shown as waveform 404 in FIG. 4.

The voltage level V_ON1 and V_ON2 of voltage V_ACR during which transistor 102 conducts may depend on how close times t0 and t5 are chosen to be to the turnover times t2 and t7 of voltage V_AC. The closer the times t0 and t5 are to the respective turnover times t2 and t7, the smaller V_ON1 and V_ON2 will be. For example, times t1 and t6 may be chosen, for example by choosing time interval T0, so that V_ON1 is 10% or 5% of the maximum value V_M of V_AC. As an example, for V_M=230 V, V_ON1 and V_ON2 may be 10 V to 20 V. In an extreme case, the transistor 102 may be kept in a conducting state just before the turnover point at time t2, so that t1=t2=t3 and t6=t7=t8 with V_ON1=V_ON2=0 V. Because of the values of V_ON1 and V_ON2 are small with regard to V_M and since the transistor 102 is only closed once per period, the power consumption due to the transistor 102 conducting and due to any circuit connected to the transistor 102 will be small. The detection of the change of a voltage, used for example in AC-detection, may thus meet the power consumption requirements in standby mode.

The predetermined duration TC, that is the time interval during which the transistor 102 is closed, may be chosen to be long enough to discharge parasitic capacitors to have a voltage equal to voltage V_AC. On the other hand, the predetermined duration TC may be chosen to be as short as possible to further reduce power consumption when the transistor 102 is conducting. For example, the predetermined duration TC may be TC=1 ms. It may lie in a region of 0.8 . . . 1.2 ms, 0.5 . . . 1.5 ms or 0.2 . . . 2.0 ms. The transistor 102 may be closed and opened before the turnover points t2 and t7 are reached. In other words, the transistor 102 may be non-conducting to act as a sensor before voltage V_ACR (and voltage V_DS) changes from decreasing to increasing (or vice versa) so that current I_G may change polarity, which may be easier to detect. The total duration of the predetermined duration TC and the predetermined time interval T0 together may be less than the period T_AC of the voltage, for example voltage V_AC, that is TC+TO<T_AC.

The transistor 102 may conduct as long as V_ACR is above a threshold of the transistor 102. In an embodiment, V_ACR may fall below the threshold of the transistor 102. The threshold may define a voltage window during which a change in V_DS can be detected.

Voltage V_GS may be regulated to a constant value to keep the transistor 102 in a non-conducting state. For a sinusoidal voltage, current I_G may be shifted in phase by a quarter period to the voltage V_DS. Current I_G may be distorted in amplitude from the shape of the voltage, for example a sine wave, due to the voltage dependence of the capacitance C_GD. A zero-crossing of the voltage applied (or coupled) to the controlled terminals of the transistor 102 may lead to a maximum or a minimum in the current I_G, depending on if the voltage is increasing or decreasing at the zero-crossing. The maximum or minimum in the current I_G may be detected using a threshold sensor, such as a comparator, for example with a positive, a negative or both a positive and a negative threshold.

FIG. 5 shows an embodiment 500 of a power supply, for example a switched-mode power supply (SMPS). The power supply may include an input 504 at which a voltage V_AC may be applied. The voltage V_AC may be an alternating voltage, such as a mains voltage with a voltage of 120 V and a frequency of 60 Hz or a voltage of 230 V and a frequency of 50 Hz. 4. The input 504 may have pins configured to fit into a socket, for example a mains outlet. The pins may be accessible or touchable by a human person.

The power supply may include a filter 502 coupled to the input 504. The filter 502 may be an electromagnetic interference (EMI)-filter, an electromagnetic compatibility (EMC) filter or a line filter. It may attenuate electromagnetic interference from the rest of the power supply to the voltage V_AC at the input 504, and vice versa. The filter 502 may include chokes 505 and 507 coupled between a respective pin of the input 504 and a respective node 501 and 503. The filter 502 may further include a capacitor 506 coupled between nodes 501 and 503. While only one capacitor 506 is shown, the filter 502 may have more than one capacitor, which may need to be discharged.

Capacitor 506 may be an X-capacitor that is connected across the line to suppress transients across the line. Capacitor 506 may still be charged to the voltage at the input 504 when the power supply is separated from the socket. Since chokes 505 and 507 may act as short circuits for DC-voltage, the voltage of the capacitor 506 may be present at the pins of the input 504. Consequently, a person handling the power supply, for example after removing it from the socket, may suffer an electric shock if he touches the pins. To prevent this, the capacitor 506 may be discharged by activating a power stage 516 or a start-up circuit 509 of the power supply. It may be necessary to detect if no voltage V_AC is present so that the at least one capacitor 506 may be discharged when the power supply is removed from the socket.

The voltage between nodes 501 and 503 may be rectified, for example by a rectifier 508, for example a half-wave or full-wave rectifier. The rectified voltage may be provided at nodes 510 and 512. A capacitor 514 may be connected across nodes 510 and 512 to smoothen the rectified voltage. The rectified and smoothened voltage may be supplied to the power stage 516. Node 512 may be at a ground potential GND.

The power stage 516 may be a converter or an inverter. It may be a switched-mode converter, a buck-converter, a boost converter or a buck-boost converter. It may be a pulse width modulated (PWM) boost converter for a power factor correcting (PFC) circuit. The power stage 516 may have an output 517 to which a load 518 may be connected. The load 518 may be powered by a voltage that was converted by the power stage 516.

The power stage 516 may have an auxiliary output 520 for supplying a control circuit 538 with power. A diode 524 may couple the auxiliary output 520 to a supply input 542 of the control circuit 538. The diode 524 may be connected such that current flows from the power stage 516 to the control circuit 538 and such that no current flows from the control circuit 538 to the power stage 516. A capacitor 526 may smoothen a voltage Vcc at the supply input 542 of the control circuit 538. The control circuit 538 may control the power stage 516 by providing a control signal 522 to the power stage 516. The control signal 522 may, for example, adjust the output voltage or current of the power stage 516.

During operation of the power supply, the control circuit 538 may be powered by the auxiliary output 520 of the power stage 516. However, when the power supply is not connected to an AC-signal at its input 504, for example if the power supply is not plugged into a mains outlet, the power stage 516 is not powered and cannot provide power to the control circuit 538 via the auxiliary output 520. When the control circuit 538 is not powered, it cannot control the power stage 516 to provide power.

During the time, that the power stage 516 cannot provide power to the control circuit 538, the control circuit 538 may be powered by a start-up circuit 509. The start-up circuit 509 may be any circuit that supplies the control circuit 538 with power independent of the power stage 516. The start-up circuit may be coupled to the signal V_AC. It may include a first diode 528, a second diode 530, a resistor 534, a switch 102, and a third diode 536. The first and second diodes 528, 530 may be coupled (or connected) to nodes 501 and 503, respectively. They may each provide a rectified voltage at a node 527. The resistor 534, the switch 102 and the diode 536 may be coupled in series to each other. The resistor 534 may be coupled between node 527 and a node 535. The switch 102 may be coupled between node 535 and a node 537. The third diode 536 may be coupled between node 537 and node 525.

The first and second diodes 528, 530 may have parasitic capacitances, which may be represented by an equivalent capacitor 532 coupled between node 527 and ground potential GND. Using both the first and second diode 528, 530 instead of using only one diode may allow a faster charging of the capacitor 526. However, rectification may also be achieved with only one of the first diode 528 and the second diode 530. In this case, the other of the diodes 528, 530 may be removed. Using only one diode may reduce the parasitic capacitance.

The resistance R of the resistor 534 may be chosen to limit the current flowing, for example, for charging the capacitor 526.

The switch 102 may activate (when it is closed or conducting) or deactivate (when it is open or non-conducting) the start-up circuit 509. It may be like the switch described in conjunction with FIGS. 1 to 4. For the purpose of illustrating, the switch 102 may be a transistor, for example, a MOSFET, for example, a superjunction transistor. However, the switch 102 may any other kind of suitable switch or transistor. It may be a depletion transistor, that is normally conducting (or “ON”) at zero gate-source voltage. The switch 102 may therefore conduct without the need of a positive voltage V_GS to be applied. In other words, it may provide power to charge the capacitor 526 without requiring any signal from the control circuit 538.

The capacitor 526 may remain charged even if the power supply is removed from the mains socket. It may therefore continue to power the control circuit 538 which controls the transistor 102 after this time. The third diode 536 may prevent a flow of current from the capacitor 526 into the start-up circuit 509.

When transistor 102 is closed, current may flow through the start-up circuit 509 which may charge capacitor 526. In other words, the transistor 102 may be configured to be in a conducting state to perform a function, for example to activate the start-up circuit 509. The voltage across the capacitor 526 may then increase to an operating voltage Vcc required for operating the control circuit 538. Once the operating voltage Vcc is reached, the control circuit 538 may start its operation and control the power stage 516 via the control signal 522. The control circuit 538 may have a power management circuit 541 to measure the voltage at its supply input 542.

The control circuit 538 may be coupled to the transistor 102. It may open transistor 102 once the power stage 516 provides enough power at its auxiliary output 520 to power the control circuit 538. The control circuit 538 may also open transistor 102 during a standby mode of the power supply, in order to reduce power consumption by stopping a current flow through the start-up circuit 509. During standby, the control circuit 538 may be powered by the power stage 516 or the energy stored in capacitor 526.

When the transistor 102 is non-conducting, it may be used for detecting (or sensing or monitoring) if a signal V_AC or a changing signal V_AC is present at the input 504. The detecting circuit 301 may be part of the control circuit 538. It may evaluate the gate current I_G of the switch 102, as described in conjunction with FIG. 3 and FIG. 4. If no signal V_AC or no change in signal V_AC is detected, the control circuit 538 may provide a signal 520 to the power stage 516 to activate it, that is, to convert energy. The power stage 516 may then discharge the capacitor 506 of the filter 502 by converting the energy stored in the capacitor 506 and dissipating it in itself and/or the load 518 connected to it. Alternatively or additionally, the control circuit 538 may provide a signal to the gate G of the transistor 102 for the transistor 102 to become conducting. The capacitor 506 may be discharged via the start-up circuit 509. With a discharged capacitor 506, there is no risk of electric shock when the power supply is removed from the mains outlet.

While FIG. 5 shows the switch 102 as being a transistor for connecting and disconnecting a start-up circuit, other switches may be used for monitoring a voltage. The switches may have the same characteristics as the switches (or transistors) 102 described above. The switch may need to be in a non-conducting mode for at least some time to be able to act as a sensor. For example, the switch may be a transistor 550 of a power stage 516, that is, a switch 550 that controls when energy is transferred into an energy storage and when energy is transferred out of the energy storage. The energy storage may be an inductor 552 and the energy may be stored in the form of the magnetic field of the inductor 552. In other words, the transistor 102 may be configured to be in a conducting state to perform a function, for example to transfer energy into the magnetic field of the inductor of the power stage. The switch 550 may be alternating opened (non-conducting) and closed (conducting) to set the output of the power stage 516. When it is open, the control terminal (or gate G of the transistor) of the switch 550 may be monitored to determine if a change in voltage at a node 555 is present or not, for example if there is a valley in the voltage or if the voltage has a zero-crossing. By monitoring the control terminal G of the switch 550, it is no longer necessary to provide an auxiliary winding for valley detection or zero detection.

The voltage across the controlled terminals of the switch should be able to change freely, that is, be able to follow a voltage that is to be measured. As an example, the voltage across the controlled terminals may be fixed by a voltage of a capacitor. For this reason, the circuit in FIG. 5 shows diodes 528 and 530 for a separate rectification instead of using the voltage rectified by rectifier 508 since this voltage is coupled to smoothing capacitor 514, which may remain charged even if voltage V_AC is zero. For the same reason, parasitic capacitor 532 is discharged before monitoring, as was described in conjunction with FIG. 4.

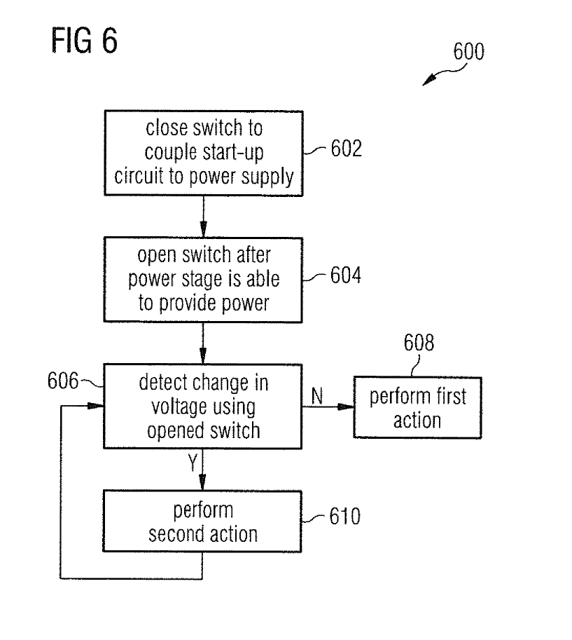

FIG. 6 shows an embodiment 600 of a flow chart of a method. The method may be for operating a power supply. The method may use the circuits, switches, transistors, power supplies and start-up circuits described in conjunction with FIGS. 1 to 5.

In step 602, the power supply is started-up, for example by closing a switch or by placing a transistor in a conducting state. The switch or transistor may activate a start-up circuit that is coupled to a voltage, for example to a mains voltage. The start-up circuit may provide a voltage to power a control circuit, for example of a power stage. The control circuit may provide signals to the power stage, for example to operate a switch in the power stage. The power stage may be coupled to the same voltage as the start-up circuit and may provide an output voltage, for example a DC output voltage. The power stage may also provide another output voltage which may be used to power the control circuit.

In step 604, the power stage provides enough power to power the control circuit. The start-up circuit no longer needs to supply power to the control circuit and the switch or transistor may be turned off, that is rendered non-conducting. The transistor may also be turned off when the circuit is in standby, thus decoupling the start-up circuit from the voltage, so that power consumptions requirements may be met during standby.

In step 606, the transistor is in its non-conducting state and may be used as a sensor, for example for the voltage that the transistor is coupled to. The transistor may indicate if a voltage or a change in voltage is present. It may be used as an AC-detector for the voltage to which it is coupled. It may detect a valley or a zero crossing of the voltage. However, the transistor may be used to detect any kind of change in the voltage. If no voltage or no change in voltage is detected, for example during a predefined time interval or before another event is signaled by the control circuit, the flow chart may continue with step 608. If a voltage or a change in voltage has been detected, the flow chart may continue with step 610.

In step 608, a first action may be performed if no voltage or no change in voltage has been detected in step 606. For example, as a first action, one or more capacitors may be discharged. The capacitor may be part of a filter, such as an EMI-filter. The capacitor may be coupled to mains plug connectors or pins. When the plug is inserted into a mains socket, the capacitor may be charged to mains voltage. If the plug is removed from the socket, the capacitor may still be charged to mains voltage and touching the mains plug connectors or pins may lead to an electric shock. This kind of situation may be detected if no voltage or no change in voltage has been detected in step 606. The capacitor may, for example, be discharged by a separate switch, or by closing the switch for the start-up circuit or the power stage.

As another example of the first action, a switch of a power stage may stay open, that is remain in a non-conducting state, for example until a time out criterion is fulfilled. For example, the change in voltage may be a valley (or a local minima) of the voltage and the switch may be closed at a low voltage which may reduce the requirements of the switch and may reduce losses during switching and may reduce electromagnetic interference. If no change in voltage has been detected, the valley has not yet been found.

In step 610, a second action may be performed if a voltage or a change in voltage has been detected in step 606. For example, as a second action, the transistor may be closed, that is placed in a conducting state, for a predetermined duration, as was described in conjunction with FIG. 4. Closing the transistor may discharge parasitic capacitances. Discharging the parasitic capacitances may lead to a more accurate detection to see if a voltage is present.

As another example of the second action, a switch of a power stage may be closed, that is placed in a conducting state. For example, the change in voltage may be a zero-crossing and the switch may be closed at zero (or very low) voltages which may reduce the requirements of the switch and may reduced losses during switching. This may also be used in zero voltage switching (ZVS) applications to detect the zero crossing.

Step 610 may be optional.

After step 610, the flow may return to step 606 to detect further voltages or changes in voltage.

The embodiments are not limited to examples given; they can include other kinds of applications, for example in power factor correction (PFC) circuits, boost converters and flyback converters, high-voltage alternating current applications, and are not limited to power supplies.

While the invention has been particularly shown and described with reference to specific embodiments, it should be understood by those skilled in the art that various changes in form and detail may be made therein without departing from the spirit and scope of the disclosure, including as defined by the appended claims. The scope of the disclosure is thus indicated by the appended claims and all changes which come within the meaning and range of equivalency of the claims are therefore intended to be embraced.

Alternately and/or additionally, the scope of the disclosure is specifically intended to include without limitation at least the embodiments described in the enumerated clauses below. Equivalents thereof are also explicitly embraced.
1. A circuit, comprising:
   a transistor, wherein a voltage is coupled across two controlled terminals of the transistor and wherein the transistor is configured to be in a non-conducting state; and
   a detection circuit coupled to a control terminal of the transistor, wherein the detection circuit is configured to detect at least one of:
      a signal due to a voltage coupled across the two controlled terminals;
      a signal due to a change in the voltage coupled across the two controlled terminals; and
      a change in a signal at the control terminal due to a change in the voltage coupled across the two controlled terminals.
2. The circuit of clause 1, wherein
   the signal is a current flowing through the control terminal; and
   the detection circuit comprises a driver circuit configured to at least one of:
      provide; and
      regulate
   a voltage between the control terminal and one of the controlled terminals to a constant value.
3. The circuit of clause 1 or 2, wherein
   the detection circuit comprises an evaluation circuit configured to detect at least one of:
      at least one of the signal and the change in the signal exceeding or falling below a threshold; and
      at least one of the signal and the change in the signal changing in polarity.
4. The circuit of one of clauses 1 to 3, wherein
   the detection circuit further comprises a driver controller configured to provide signals to the driver circuit to place the transistor in one of a conducting state and a non-conducting state.
5. The circuit of one of clauses 1 to 4, further comprising:
   a rectifier coupled between the voltage and the two controlled terminals,
   wherein the driver controller provides signals to the driver circuit to place the transistor in a conducting state for a predetermined duration after a predetermined time interval after a change in the signal has been detected by the evaluation circuit.
6. The circuit of clause 5, wherein
   the voltage applied to the controlled terminals is periodic; and
   the duration of the predetermined time interval and the predetermined duration together is less than a period of the voltage.
7. The circuit of one of clauses 1 to 6, wherein
   the transistor is one of:
      a Metal-Oxide-Semiconductor Field-Effect-Transistor;
      a field plate trench transistor; and
      a superjunction transistor.
8. The circuit of clause 7, wherein
   a capacitance of a gate-drain capacitor of the transistor is at least a factor 20 larger at a voltage of 0 V coupled across the two controlled terminals than at a rated breakdown voltage of the transistor.
9. The circuit of clause 7 or 8, wherein
   a capacitance of a gate-drain capacitor of the transistor depends on the voltage across the controlled terminals by a factor of more than two to three orders of magnitude for voltages less than a corner voltage than for voltages greater than the corner voltage.
10. The circuit of one of clauses 1 to 9, further comprising:
   a plurality of transistors, wherein
   drains of transistors of the plurality of transistors and a drain of the transistor are coupled together;
   sources of transistors of the plurality of transistors and a source of the transistor are coupled together;
   gates of transistors of the plurality of transistors are coupled together; and
   a gate of the transistor is not connected to the gates of the transistors of the plurality of transistors.
11. The circuit of one of clauses 1 to 10, further comprising:
   a start-up circuit; wherein
   the transistor is configured to activate and deactivate the start-up circuit.
12. The circuit of one of clauses 1 to 10, further comprising:
   a power stage; wherein
   the transistor is a switch transistor of the power stage.
13. The circuit of one of clauses 1 to 12, further comprising:
   a filter comprising at least one capacitor; wherein
   the detection circuit is configured, when no change in the signal has been detected during a predetermined time interval, to discharge the at least one capacitor by at least one of:
      activating a power stage; and
      placing the transistor in a conducting state.
14. A method for operating a circuit, comprising:
   configuring a transistor to be in a conducting state to perform a function; and
   detecting a change in a voltage coupled between two controlled terminals of the transistor by monitoring a control terminal of the transistor.
15. The method of clause 14, further comprising:
   configuring the transistor to be in a non-conducting state before detecting the change in a voltage.
16. The method of clause 14 or 15, wherein
   performing the function comprises at least one of:
      activating a start-up circuit; and
      transferring energy into a magnetic field of an inductor of a power stage.
17. The method of one clauses 14 to 16, wherein
   monitoring the control terminal comprises at least one of:
   measuring a voltage across the control terminal and one of the controlled terminals; and
   comparing a current flowing through the control terminal to at least one threshold while one of:
      regulating a voltage between the control terminal and one of the controlled terminals to a constant value; and
      providing a predetermined voltage between the control terminal and one of the controlled terminals.
18. The method of one of clauses 14 to 17, further comprising:
   rectifying an alternating voltage to provide the voltage to the controlled terminals of the transistor; and
   detecting a zero-crossing of the alternating voltage by at least one of:
      a current flowing into the control terminal and crossing a first threshold; and
      a current flowing out of the control terminal and crossing a second threshold.
19. The method of clause 18, wherein
   the alternating voltage is periodic; and
   the method further comprises configuring the transistor to be in a conducting state for a predetermined duration starting at a predetermined time after a zero crossing has been detected, wherein the predetermined time is longer than a quarter period of the alternating voltage; and
   the total duration of the predetermined time and the predetermined duration is shorter than half a period of the alternating voltage.
20. The method of one of clauses 14 to 19, further comprising:
   when no change in voltage is detected during a predetermined time interval, discharging at least one capacitance of a filter by at least one of:
      configuring the transistor to be in a conducting state; and
      activating a power stage.
21. The method of clause 14, further comprising:
   configuring the transistor to be in a non-conducting state after detecting the change in the voltage coupled between the two controlled terminals of the transistor.
22. A method for operating a power supply, comprising:
   coupling a start-up circuit of a controller of a power stage of the power supply to a voltage using a transistor to provide power to the controller when the power stage is unable to provide power to the controller;
   configuring the transistor to be in a non-conducting state after the power stage is able to provide power to the controller; and
   detecting a change in the voltage by monitoring a control terminal of the transistor when the transistor is in the non-conducting mode.
23. A detection circuit, configured to be coupled to a control terminal of a transistor, wherein the detection circuit is configured to detect at least one of:
   a signal at the control terminal due to a voltage coupled across two controlled terminals of the transistor;
   a signal at the control terminal due to a change in a voltage coupled across two controlled terminals of the transistor; and
   a change in a signal at the control terminal due to a change in a voltage coupled across two controlled terminals of the transistor.

What is claimed is:

1. A circuit, comprising:
a transistor, wherein a voltage is coupled across two controlled terminals of the transistor and wherein the transistor is configured to be in a non-conducting state; and
a detection circuit coupled to a control terminal of the transistor, wherein the detection circuit is configured to detect at least one of:
a signal due to a voltage coupled across the two controlled terminals;
a signal due to a change in the voltage coupled across the two controlled terminals; and
a change in a signal at the control terminal due to a change in the voltage coupled across the two controlled terminals.

2. The circuit of claim 1, wherein
the signal is a current flowing through the control terminal; and
the detection circuit comprises a driver circuit configured to at least one of:
provide; and
regulate
a voltage between the control terminal and one of the controlled terminals to a constant value.

3. The circuit of claim 1, wherein
the detection circuit comprises an evaluation circuit configured to detect at least one of:
at least one of the signal and the change in the signal exceeding or falling below a threshold; and
at least one of the signal and the change in the signal changing in polarity.

4. The circuit of claim 3, wherein
the detection circuit further comprises a driver controller configured to provide signals to the driver circuit to place the transistor in one of a conducting state and a non-conducting state.

5. The circuit of claim 4, further comprising:
a rectifier coupled between the voltage and the two controlled terminals,
wherein the driver controller provides signals to the driver circuit to place the transistor in a conducting state for a predetermined duration after a predetermined time interval after a change in the signal has been detected by the evaluation circuit.

6. The circuit of claim 5, wherein
the voltage applied to the controlled terminals is periodic; and
the duration of the predetermined time interval and the predetermined duration together is less than a period of the voltage.

7. The circuit of claim 1, wherein
the transistor is one of:
a Metal-Oxide-Semiconductor Field-Effect-Transistor;
a field plate trench transistor; and
a superjunction transistor.

8. The circuit of claim 7, wherein
a capacitance of a gate-drain capacitor of the transistor is at least a factor 20 larger at a voltage of 0 V coupled across the two controlled terminals than at a rated breakdown voltage of the transistor.

9. The circuit of claim 7, wherein
a capacitance of a gate-drain capacitor of the transistor depends on the voltage across the controlled terminals by a factor of more than two to three orders of magnitude for voltages less than a corner voltage than for voltages greater than the corner voltage.

10. The circuit of claim 1, further comprising:
a plurality of transistors, wherein
drains of transistors of the plurality of transistors and a drain of the transistor are coupled together;
sources of transistors of the plurality of transistors and a source of the transistor are coupled together;
gates of transistors of the plurality of transistors are coupled together; and
a gate of the transistor is not connected to the gates of the transistors of the plurality of transistors.

11. The circuit of claim 1, further comprising:
a start-up circuit; wherein
the transistor is configured to activate and deactivate the start-up circuit.

12. The circuit of claim 1, further comprising:
a power stage; wherein
the transistor is a switch transistor of the power stage.

13. The circuit of claim 1, further comprising:
a filter comprising at least one capacitor; wherein
the detection circuit is configured, when no change in the signal has been detected during a predetermined time interval, to discharge the at least one capacitor by at least one of:
activating a power stage; and
placing the transistor in a conducting state.

14. A method for operating a circuit, comprising:
configuring a transistor to be in a conducting state to perform a function; and
detecting a change in a voltage coupled between two controlled terminals of the transistor by monitoring a control terminal of the transistor.

15. The method of claim 14, further comprising:
configuring the transistor to be in a non-conducting state before detecting the change in the voltage coupled between the two controlled terminals of the transistor.

16. The method of claim 15, wherein
performing the function comprises at least one of:
activating a start-up circuit; and
transferring energy into a magnetic field of an inductor of a power stage.

17. The method of claim 14, wherein
monitoring the control terminal comprises:
at least one of:
measuring a voltage across the control terminal and one of the controlled terminals; and
comparing a current flowing through the control terminal to at least one threshold while one of:
regulating a voltage between the control terminal and one of the controlled terminals to a constant value; and
providing a predetermined voltage between the control terminal and one of the controlled terminals.

18. The method of claim 17, further comprising:
rectifying an alternating voltage to provide the voltage to the controlled terminals of the transistor; and
detecting a zero-crossing of the alternating voltage by at least one of:
a current flowing into the control terminal and crossing a first threshold; and
a current flowing out of the control terminal and crossing a second threshold.

19. The method of claim 18, wherein
the alternating voltage is periodic; and
the method further comprises configuring the transistor to be in a conducting state for a predetermined duration starting at a predetermined time after a zero crossing has been detected, wherein the predetermined time is longer than a quarter period of the alternating voltage; and
the total duration of the predetermined time and the predetermined duration is shorter than half a period of the alternating voltage.

20. The method of claim 14, further comprising:
when no change in voltage is detected during a predetermined time interval, discharging at least one capacitance of a filter by at least one of:
configuring the transistor to be in a conducting state; and
activating a power stage.

21. The method of claim 14, further comprising:
configuring the transistor to be in a non-conducting state after detecting the change in the voltage coupled between the two controlled terminals of the transistor.

22. A method for operating a power supply, comprising:
coupling a start-up circuit of a controller of a power stage of the power supply to a voltage using a transistor to provide power to the controller when the power stage is unable to provide power to the controller;
configuring the transistor to be in a non-conducting state after the power stage is able to provide power to the controller; and
detecting a change in the voltage by monitoring a control terminal of the transistor when the transistor is in the non-conducting mode.

23. A detection circuit, configured to be coupled to a control terminal of a transistor, wherein
the detection circuit is configured to detect at least one of:
a signal at the control terminal due to a voltage coupled across two controlled terminals of the transistor;
a signal at the control terminal due to a change in a voltage coupled across two controlled terminals of the transistor; and
a change in a signal at the control terminal due to a change in a voltage coupled across two controlled terminals of the transistor.
